(19) United States
(12) Patent Application Publication
(10) Pub. No.: US 2025/0379037 A1
(43) Pub. Date: Dec. 11, 2025

(54) APPARATUS FOR PROCESSING SUBSTRATE

(71) Applicant: ISAC RESEARCH INC., Daejeon (KR)

(72) Inventors: Hyung Sang PARK, Daejeon (KR); Seong Jun JEONG, Daejeon (KR); Ji Hye KIM, Daejeon (KR); Min Ho CHOI, Daejeon (KR)

(73) Assignee: ISAC RESEARCH INC., Daejeon (KR)

(21) Appl. No.: 19/207,660

(22) Filed: May 14, 2025

(30) Foreign Application Priority Data
Jun. 5, 2024 (KR) 10-2024-0073749

(51) Int. Cl. H01J 37/32; C23C 16/455

(52) U.S. Cl. CPC H01J 37/32357; C23C 16/45536; C23C 16/45565; H01J 37/3244; H01J 37/32697; H01J 37/32715; H01J 2237/3321

(57) ABSTRACT

An apparatus for processing a substrate according to one aspect of the present disclosure includes a chamber including a processing space in which the substrate is accommodatable and processible, a susceptor coupled to the chamber to support the substrate in the processing space, a gas supply device that is installed in a upper portion of the chamber and supplies a gas toward the susceptor, and an RF power device configured to supply RF power to at least a portion of the gas supply device in order to form remote plasma in the gas supply device or to form direct plasma in the processing space.

### CROSS-REFERENCE TO RELATED APPLICATION

The present application claims priority under 35 U.S.C. § 119(a) to Korean Patent Application No. 10-2024-0073749, filed in the Korean Intellectual Property Office on Jun. 5, 2024, the entire contents of which application is incorporated herein by reference.

### STATEMENT REGARDING SPONSORED RESEARCH OR DEVELOPMENT

The research and development of the present disclosure were conducted with the support of the Korea Planning & Evaluation Institute of Industrial Technology (KEIT) with the financial resources of the Ministry of Trade, Industry and Energy (MOTIE) (Project Number: RS-2024-00406482, Detailed Project identifier: 2410000635).

### BACKGROUND OF THE INVENTION

### Field of the Invention

The present disclosure relates to semiconductor manufacturing, and more specifically, to an apparatus for processing a substrate.

### Description of Related Art

In order to manufacture semiconductor devices, various processes for processing a substrate are performed in a substrate processing apparatus under a vacuum atmosphere. For example, processes such as loading a substrate into a chamber and depositing a thin film on the substrate or etching the thin film can be performed. The substrate is supported on a susceptor installed in the chamber, and the substrate can be processed by injecting a process gas to the substrate through a gas supply device installed above the susceptor.

In such a substrate processing apparatus, when a thin film is deposited on the substrate, a gas can be activated using plasma. A gas activated using remote plasma formed outside the chamber can be supplied into the chamber, or a gas can be activated in the chamber using plasma formed directly inside the chamber and supplied to the substrate.

However, in the case of using direct plasma, a deposition rate can be increased when a thin film is formed, but plasma damage may occur to a substrate. On the other hand, in the case of using remote plasma, there is a problem of a low deposition rate when a thin film is formed. Accordingly, it is required to control a type of plasma as needed.

### SUMMARY OF THE INVENTION

The present disclosure is intended to solve various problems including the above-mentioned problems, and an object thereof is to provide an apparatus for processing a substrate that can selectively use remote plasma and direct plasma as needed. However, these problems are exemplary, and the scope of the present disclosure is not limited thereby.

An apparatus for processing a substrate according to one aspect of the present disclosure for solving the problems includes: a chamber including a processing space in which the substrate is accommodatable and processible; a susceptor coupled to the chamber to support the substrate in the processing space; a gas supply device that is installed in a upper portion of the chamber and supplies a gas toward the susceptor; and an RF power device configured to supply RF power to at least a portion of the gas supply device in order to form remote plasma in the gas supply device or to form direct plasma in the processing space.

In the apparatus for processing a substrate, the gas supply device may include a shower head coupled to the chamber to inject a gas into the processing space, a top plate that is disposed to be apart from the shower head and has a gas inlet formed therein, and an insulating side wall interposed between an end portion of the shower head and an end portion of the top plate to define a reaction space between the top plate and the shower head, and the RF power device may be selectively connected to the top plate or the shower head.

In the apparatus for processing a substrate, in a case in which the RF power device is selectively connected to the shower head to supply the RF power to the shower head and the susceptor is connected to a ground portion, the direct plasma may be formed in the processing space.

In the apparatus for processing a substrate, in a case in which the RF power device is selectively connected to the shower head to supply the RF power to the shower head and the susceptor and the top plate are connected to the ground portion, the remote plasma may be formed in the reaction space, and the direct plasma may be formed in the processing space.

In the apparatus for processing a substrate, in a case in which the RF power device is selectively connected to the top plate to supply the RF power to the top plate and the shower head is connected to the ground portion, the remote plasma may be formed in the reaction space.

The apparatus for processing a substrate may further include a bias power supply unit selectively connected to the susceptor to apply a bias voltage to the susceptor.

In the apparatus for processing a substrate, a precursor may be supplied or a reaction gas may be supplied onto the substrate through the gas supply device to form a thin film on the substrate using an atomic layer deposition (ALD) method, the bias voltage may be applied to the susceptor through the bias power supply unit in the case of supplying the precursor, and the bias voltage may not be applied to the susceptor in the case of supplying the reaction gas.

In the apparatus for processing a substrate, in a case in which the remote plasma is formed in the reaction space or the direct plasma is formed in the processing space, the bias voltage may be applied to the susceptor through the bias power supply unit.

In the apparatus for processing a substrate, the RF power device may include an RF power supply unit configured to generate the RF power, and a splitter connected between the RF power supply unit and the gas supply device to separate and selectively supply the RF power to the RF power to the top plate and the shower head.

In the apparatus for processing a substrate, the RF power device may include a first RF power supply unit selectively connected to the top plate via a first switch, and a second RF power supply unit selectively connected to the shower head via a second switch, and the RF power device may control the first switch and the second switch to form the remote plasma in the reaction space or to form the direct plasma in the processing space.

In the apparatus for processing a substrate, in a case in which the top plate is electrically connected to the first RF power supply unit via the first switch to be supplied with the RF power and the shower head is connected to the ground portion, the remote plasma may be formed in the reaction space.

In the apparatus for processing a substrate, in a case in which the shower head is connected to the second RF power supply unit via the second switch to be supplied with the RF power and the susceptor is connected to the ground portion, the direct plasma may be formed in the processing space.

In the apparatus for processing a substrate, the remote plasma may be formed inside the gas supply device in an initial deposition stage for forming the thin film on the substrate, and the direct plasma may be formed in the processing space in a bulk deposition stage for forming the thin film after the initial stage.

According to the apparatus for processing a substrate according to some embodiments of the present disclosure configured as described above, the remote plasma and the direct plasma can be selectively used as needed, or both can be used simultaneously. Accordingly, a deposition rate can be increased while minimizing plasma damage on the substrate. It is needless to say that the scope of the present disclosure is not limited by these effects.

### BRIEF DESCRIPTION OF THE DRAWINGS

FIG. 1 is a schematic cross-sectional view showing a substrate processing apparatus according to one embodiment of the present disclosure.

FIGS. 2 to 5 are schematic cross-sectional views showing operations of the substrate processing apparatus of FIG. 1.

FIG. 6 is a schematic cross-sectional view showing a substrate processing apparatus according to another embodiment of the present disclosure.

FIGS. 7 to 9 are schematic cross-sectional views showing operations of the substrate processing apparatus of FIG. 6.

FIG. 10 is a schematic cross-sectional view of a substrate showing an example of a method for processing a substrate according to some embodiments of the present disclosure.

### DETAILED DESCRIPTION OF THE INVENTION

Various preferred embodiments of the present disclosure will be described in detail below with reference to the accompanying drawings.

It should be understood that the embodiments of the present disclosure are provided to explain the present disclosure more completely to those having ordinary knowledge in the art, and the following embodiments may be modified in various different forms and the scope of the present disclosure is not limited to the following embodiments. Rather, these embodiments are provided to make the present disclosure more sufficient and complete and to completely convey the idea of the present disclosure to those skilled in the art. In addition, in the drawings, thicknesses or sizes of each layer are exaggerated for convenience and clarity of description.

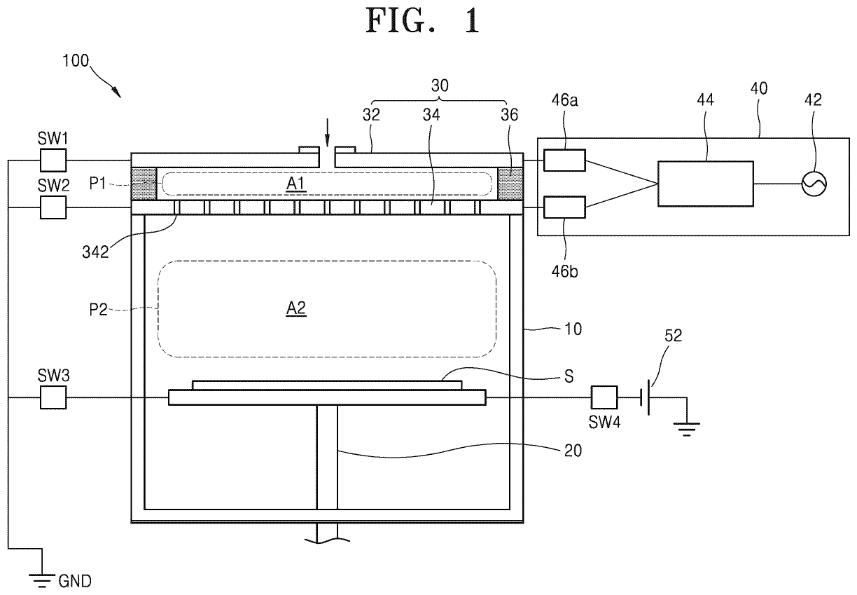

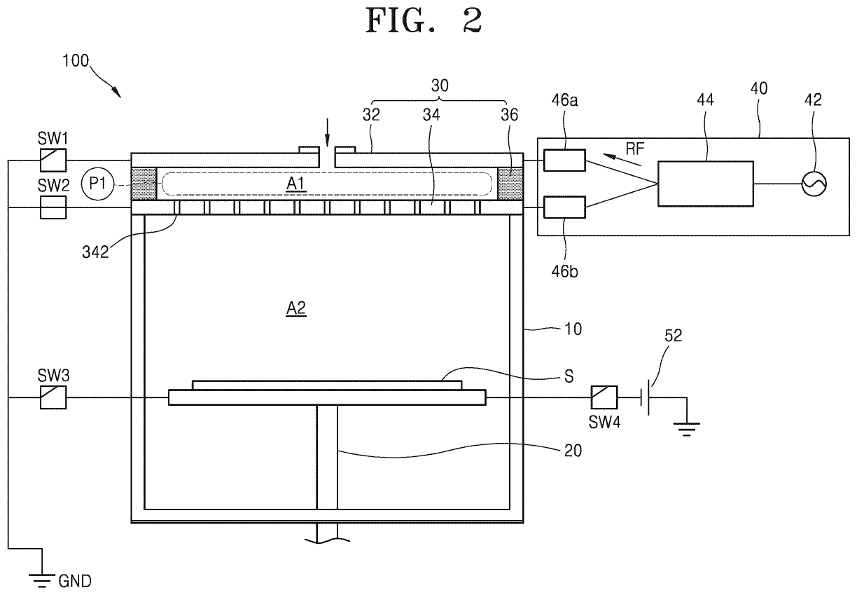

FIG. 1 is a schematic cross-sectional view showing a substrate processing apparatus 100 according to one embodiment of the present disclosure, and FIGS. 2 to 5 are schematic cross-sectional views showing operations of the substrate processing apparatus 100 of FIG. 1.

Referring to FIG. 1, the substrate processing apparatus 100 may include a chamber 10, a susceptor 20, a gas supply device 30, and a radio frequency (RF) power device 40.

For example, the chamber 10 may have a structure provided with a processing space A2 in which at least one substrate S can be accommodated and processed. The chamber 10 may be connected to a vacuum pump (not shown) to form a vacuum atmosphere. Further, the chamber 10 may be provided with an entrance (not shown) for loading or unloading the substrate S into the processing space A2.

The chamber 10 may be provided in various shapes, and for example, may include a side wall portion that defines the processing space A2 and a cover portion that is located at an upper end of the side wall portion. This chamber 10 may be applied to various chambers of all types that have sufficient strength or durability to be able to support the susceptor 20 or the gas supply device 30 therein, and may be provided with various vacuum lines, pressure gauges, various sensors, or the like.

The susceptor 20 may be coupled to the chamber 10 to support the substrate S in the processing space A2. The susceptor 20 may be a kind of rotating turntable device that is installed in the processing space A2 and supports at least one substrate S. Accordingly, the substrate S can be rotated around a rotation axis by the susceptor 20. For example, the susceptor 20 may include a plate for supporting the substrate S and a shaft for supporting the plate from below.

The gas supply device 30 may be installed in a upper portion of the chamber 10 and may supply a gas toward the susceptor 20. For example, the gas supply device 30 may be a gas distribution device that is installed in the chamber 10 and can supply various process gases, for example, such as a source gas, a purge gas, and a reaction gas, in a time-division or space-division manner toward the substrate S.

For example, the gas supply device 30 may include a top plate 32, a shower head 34, and an insulating side wall 36. For example, the shower head 34 may be coupled to the chamber 10 to inject the gas into the processing space A2. The top plate 32 may be disposed apart from the shower head 34 and may have a gas inlet formed therein. Injection holes 342 for injecting the gas in the reaction space A1 into the processing space A2 are formed in the shower head 34.

The insulating side wall 36 may be interposed between an end portion of the shower head 34 and an end portion of the top plate 32 to define the reaction space A1 between the top plate 32 and the shower head 34. The insulating side wall 36 may have a function of providing electrical insulation between the top plate 32 and the shower head 34 while defining the reaction space A1 between the top plate 32 and the shower head 34.

In some embodiments, the gas supply device 30 may be insulated from the chamber 10. For example, if the chamber 10 is made of an insulating material, the shower head 34 may be directly coupled to the chamber 10. In another example, if the chamber 10 is made of a conductive material, an insulating member (not shown) may be added between the chamber 10 and the shower head 34. For example, an insulating O-ring may be inserted between the chamber 10 and the shower head 34.

The RF power device 40 may supply RF power into the substrate processing apparatus 100. For example, the RF power device 40 may be coupled to at least a portion of the gas supply device 30 to supply the RF power to at least a portion of the gas supply device 30. For example, the RF power device 40 may include a high frequency (HF) power supply and/or a low frequency (LF) power supply, and may supply HF power and/or LF power.

In some embodiments, the RF power device 40 may supply the RF power to at least a portion of the gas supply device 30 in order to form a remote plasma P1 inside the gas supply device 30, that is, in the reaction space A1, or to form direct plasma P2 in the processing space A2. Here, both the direct plasma P2 and the remote plasma P1 are formed in the substrate processing apparatus 100, but the plasma in the reaction space A1 may be referred to as the remote plasma in that the reaction space A1 is separated from the processing space A2 and the substrate S is not located in the reaction space A1.

The direct plasma P2 may be advantageous in terms of plasma efficiency in that it is formed directly in the processing space A2 in which the substrate S is located. Accordingly, in the case of forming a thin film on the substrate S using the direct plasma P2, the deposition rate can be increased, but plasma damage can occur on the substrate S. On the other hand, since the remote plasma P1 is formed in the reaction space A1 in which there is no substrate S, supplying radicals generated using the remote plasma P1 onto the substrate S can reduce or eliminate plasma damage on the substrate S. Thus, the remote plasma P1 or direct plasma P2 can be selectively formed as needed in the substrate processing apparatus 100.

In some embodiments, the RF power device 40 may include an RF power supply unit 42 that generates the RF power and a splitter 44 connected between the RF power supply unit 42 and the gas supply device 30 to separate and selectively supply the RF power to the top plate 32 and the shower head 34. The RF power generated from the RF power supply unit 42 may be split and output from the splitter 44.

The splitter 44 may be selectively connected to the top plate 32 and the shower head 34. For example, when the splitter 44 is connected to the top plate 32, the RF power generated from the RF power supply unit 42 may be supplied only to the top plate 32 and not to the shower head 34. In another example, when the splitter 44 is connected to the shower head 34, the RF power generated from the RF power supply unit 42 may be supplied only to the shower head 34 and not to the top plate 32.

In some embodiments, an impedance matching unit 46a may be interposed between the splitter 44 and the top plate 32, and an impedance matching unit 46b may be interposed between the splitter 44 and the shower head 34. The impedance matching units 46a and 46b may perform impedance matching between the RF power supply unit 42 and the gas supply device 30 or the chamber 10.

In some embodiments, the RF power supply device 40 may be selectively connected to a portion of the gas supply device 30, for example, to the top plate 32 or the shower head 34. The top plate 32 and the shower head 34 may be made of a conductive material, and may receive the RF power from the RF power device 40 to supply the RF power to the reaction space A1 and/or the processing space A2, thereby forming a plasma atmosphere in the reaction space A1 and/or the processing space A2.

In some embodiments, the top plate 32 may be selectively connected to a ground portion GND via a switch SW1, the shower head 34 may be selectively connected to the ground portion GND via a switch SW2, and the susceptor 20 may be selectively connected to the ground portion GND via a switch SW3.

In some embodiments, as shown in FIG. 2, in a case in which the RF power device 40 is selectively connected to the top plate 32 to supply the RF power to the top plate 32 and the shower head 34 is connected to the ground portion GND, the remote plasma P1 may be formed in the reaction space A1. Here, the susceptor 20 may be floating or grounded. In this case, capacitive coupled plasma (CCP) type remote plasma P1 may be formed between the top plate 32 and the shower head 34.

More specifically, the RF power may be selectively provided to the top plate 32 through the splitter 44, the switches SW1 and SW3 may be turned off, and the switch SW2 may be turned on, thereby connecting the shower head 34 to the ground portion GND. The switch SW3 can also be selectively turned on to connect the susceptor 20 to the ground portion GND. Accordingly, the remote plasma P1 may be formed in the reaction space A1, and the direct plasma P2 may not be formed in the processing space A2.

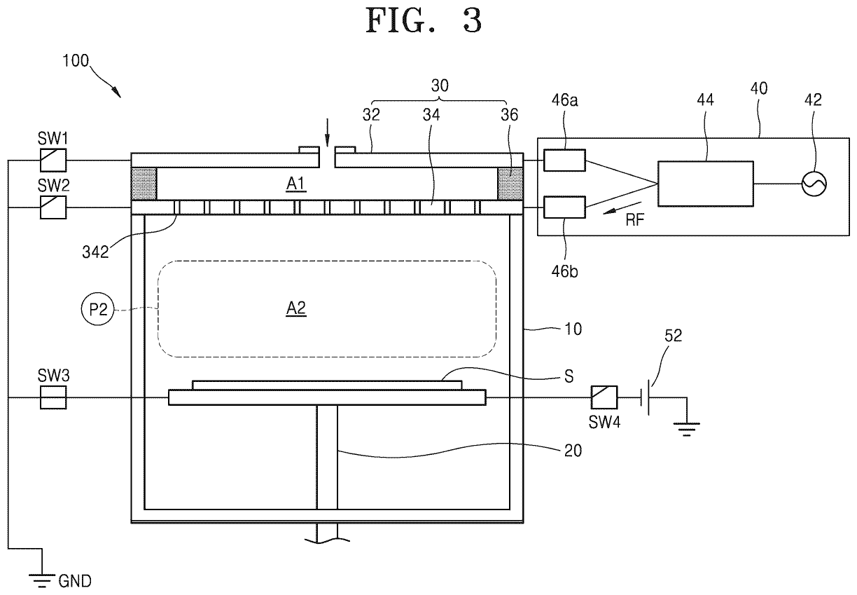

In some embodiments, as shown in FIG. 3, in a case in which the RF power device 40 is selectively connected to the shower head 34 to supply the RF power to the shower head 34 and the susceptor 20 is connected to the ground portion GND, the direct plasma P2 may be formed in the processing space A2. Here, the top plate 32 may not be supplied with the RF power and may be floating. Accordingly, capacitive coupled plasma (CCP) type direct plasma P2 may be formed between the shower head 34 and the susceptor 20.

More specifically, the RF power may be selectively provided to the shower head 34 through the splitter 44, the switches SW1 and SW2 may be turned off, and the switch SW3 may be turned on, thereby connecting the susceptor 20 to the ground portion GND. Accordingly, the direct plasma P2 may be formed in the processing space A2, and the remote plasma P1 may not be formed in the reaction space A1.

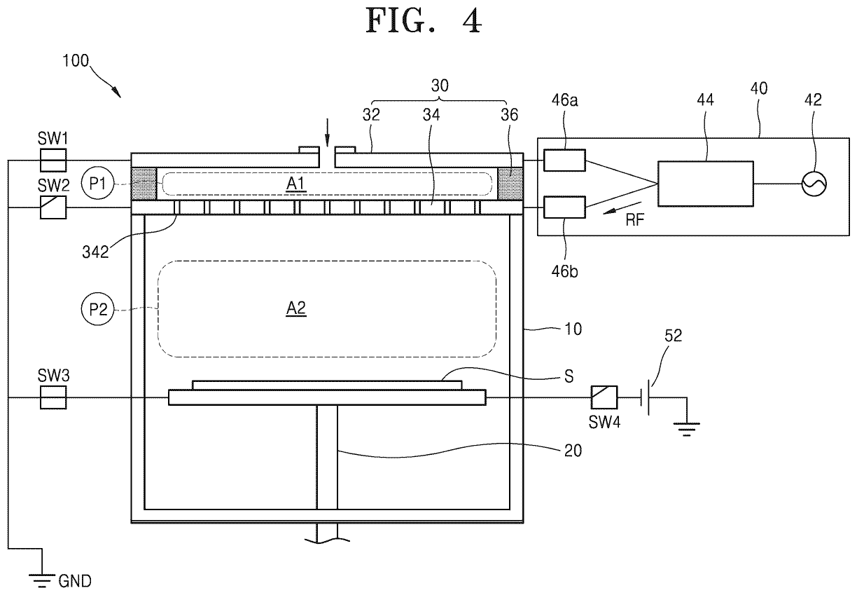

In some embodiments, as shown in FIG. 4, in a case in which the RF power device 40 is selectively connected to the shower head 34 to supply the RF power to the shower head 34 and the susceptor 20 and the top plate 32 are connected to the ground portion GND, the remote plasma P1 may be formed in the reaction space A1, and the direct plasma P2 may be formed in the processing space A2. In this case, the CCP type direct plasma P2 may be formed between the shower head 34 and the susceptor 20, and at the same time, the CCP type remote plasma P1 may be formed between the shower head 34 and the top plate 32.

More specifically, the RF power may be selectively provided to the shower head 34 through the splitter 44, the switch SW2 may be turned off, and the switches SW1 and SW3 may be turned on, thereby connecting the top plate 32 and the susceptor 20 to the ground portion GND. Accordingly, the direct plasma P2 may be formed in the processing space A2, and the remote plasma P1 may be formed in the reaction space A1.

In some embodiments, a bias power supply unit 52 selectively connected to the susceptor 20 may be added in the substrate processing apparatus 100 to apply a bias voltage to the susceptor 20. For example, the bias power supply unit 52 may apply a DC bias voltage as illustrated in FIGS. 1 to 9. However, in modified examples of these embodiments, the bias power supply unit 52 may be modified to apply an AC bias voltage or an RF bias voltage in addition to the DC bias voltage.

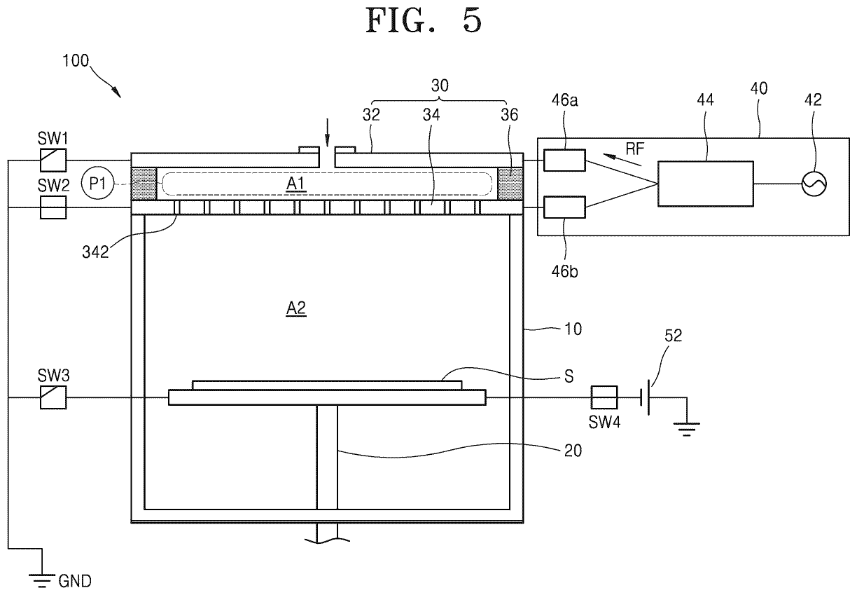

For example, as illustrated in FIG. 5, when the RF power device 40 is selectively connected to the top plate 32 to supply the RF power to the top plate 32 and the shower head 34 is grounded, thereby forming the remote plasma P1 in the reaction space A1, a bias voltage may be selectively connected to the susceptor 20 through the bias power supply unit 52. More specifically, a switch SW4 may be turned on to provide a bias voltage output from the bias power supply unit 52 to the susceptor 20. This bias power can improve deposition or etching characteristics when the substrate S is processed.

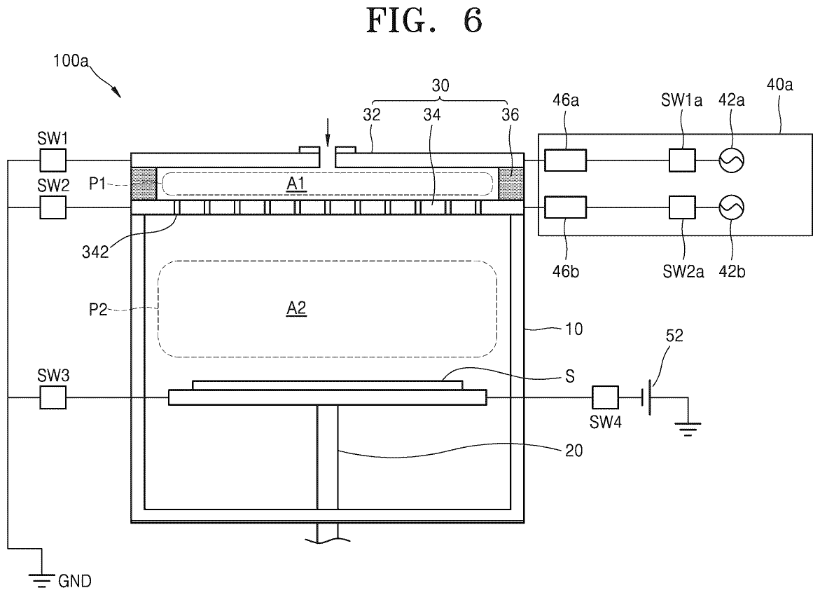

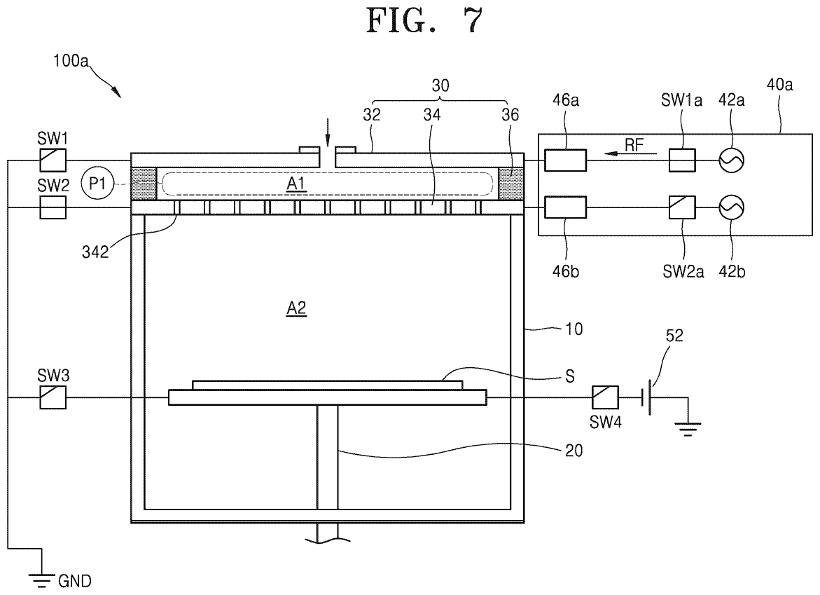

FIG. 6 is a schematic cross-sectional view showing a substrate processing apparatus 100a according to another embodiment of the present disclosure, and FIGS. 7 to 9 are schematic cross-sectional views showing operations of the substrate processing apparatus 100a of FIG. 6. The substrate processing apparatus 100a is a device obtained by modifying some of the configurations of the substrate processing apparatus 100 of FIGS. 1 to 5, and since the embodiments can be referenced from each other, any repeated description in the embodiments will be omitted.

Referring to FIG. 6, the substrate processing apparatus 100a may include the chamber 10, the susceptor 20, the gas injection device 30, and an RF power device 40a.

In the substrate processing apparatus 100a, the RF power device 40a may include a first RF power supply unit 42a that is selectively connected to the top plate 32 via a first switch SW1a and a second RF power supply unit 42b that is selectively connected to the shower head 34 via a second switch SW2a. The RF power device 40a may control the first switch SW1a and the second switch SW2a to form the remote plasma P1 in the reaction space A1 or to form the direct plasma P2 in the processing space A2.

For example, by turning on the first switch SW1a and turning off the second switch SW2a, the RF power output from the first RF power supply unit 42a may be selectively supplied to the top plate 32. In another example, by turning off the first switch SW1a and turning on the second switch SW2a, the RF power output from the second RF power supply unit 42b may be selectively supplied to the shower head 34.

In some embodiments, as shown in FIG. 7, in a case in which the RF power device 40a is selectively connected to the top plate 32 to supply the RF power to the top plate 32 and the shower head 34 is connected to the ground portion GND, the remote plasma P1 may be formed in the reaction space A1. For example, by turning on the switches SW1a and SW2 and turning off the switches SW1 and SW2a, the top plate 32 may be electrically connected to the first RF power supply unit 42a via the first switch SW1a to receive the RF power, and the shower head 34 may be connected to the ground portion GND. Accordingly, the remote plasma P1 may be formed in the reaction space A1, and the direct plasma P2 may not be formed in the processing space A2.

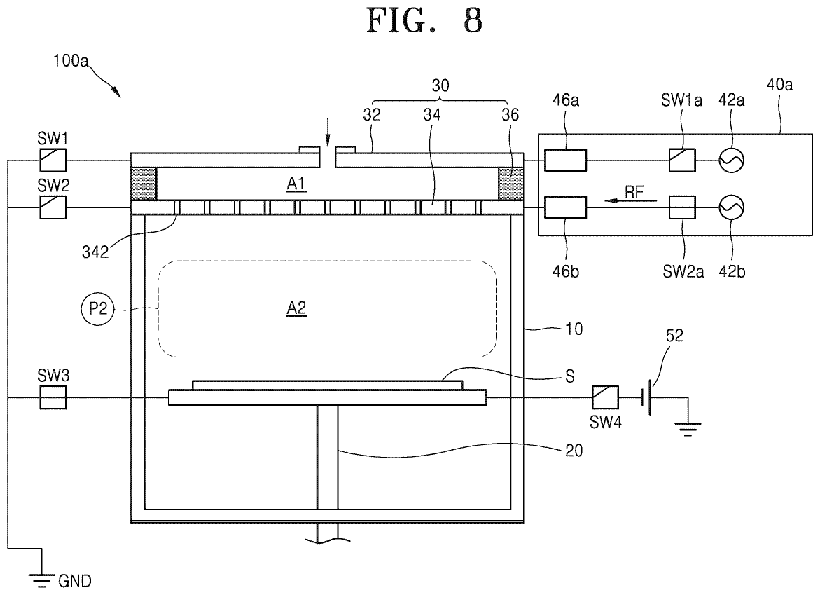

In some embodiments, as shown in FIG. 8, in a case in which the RF power device 40a is selectively connected to the shower head 34 to supply the RF power to the shower head 34 and the susceptor 20 is connected to the ground portion GND, the direct plasma P2 may be formed in the processing space A2. For example, by turning on the switches SW2a and SW3 and turning off the switches SW1a, SW1, and SW2, the shower head 34 may be connected to the second RF power supply unit 42b to receive the RF power and the susceptor 20 may be connected to the ground portion.

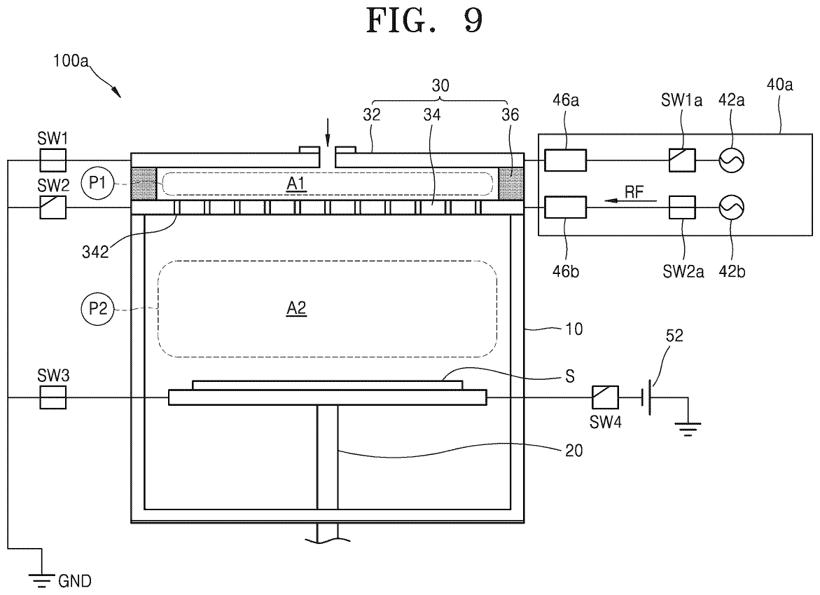

In some embodiments, as shown in FIG. 9, in a case in which the RF power device 40a is selectively connected to the shower head 34 to supply the RF power to the shower head 34 and the susceptor 20 and the top plate 32 are connected to the ground portion GND, the remote plasma P1 may be formed in the reaction space A1 and the direct plasma P2 may be formed in the processing space A2. For example, the switches SW1, W2a, and SW3 may be turned on and the switches SW1a and SW2 may be turned off.

In some embodiments, in a case in which the remote plasma P1 is formed in the reaction space A1, a bias voltage may be selectively connected to the susceptor 20 through the bias power supply unit 52.

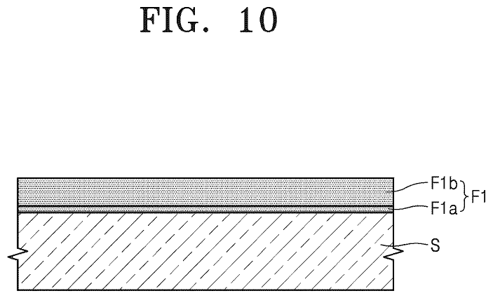

As illustrated in FIG. 10, the substrate processing apparatus 100 and 100a described above may be used to form a thin film F1 on the substrate S using an atomic layer deposition (ALD) method.

For example, in order to form the thin film F1, by repeating a cycle reaction of supplying a precursor or a source gas onto the substrate S through the gas supply device 30 and supplying a reaction gas onto the substrate S, the thin film F1 may be formed on the substrate S.

In some embodiments, when a bias voltage is selectively applied to the susceptor 20 through the bias power supply unit 52 during at least some sections of such a thin film F1 forming step, deposition efficiency of atomic layers can be improved. For example, a deposition rate of the thin film F1 can be increased by improving adhesion efficiency of the precursor or the source gas on the substrate S.

For example, the bias voltage can be selectively applied to the susceptor 20 through the bias power supply unit 52 when the precursor or the source gas is supplied, and the bias voltage may not be applied to the susceptor 20 when the reaction gas is supplied.

In some embodiments, when the remote plasma is formed in the reaction space A1 or the direct plasma is formed in the processing space A2, the bias voltage may be applied to the susceptor 20 through the bias power supply unit 52 as needed.

In some embodiments, in an initial deposition stage in which the thin film F1 is formed on the substrate S, the remote plasma P1 may be formed in the reaction space A1 inside the gas supply device 30, and in a bulk deposition stage in which the thin film F1 is formed after the initial stage, the direct plasma P2 may be formed in the processing space A2. Accordingly, in the initial deposition stage, a thin initial thin film Fla may be formed on the substrate S without plasma damage using the remote plasma P1, and in the bulk deposition stage, a thick bulk thin film Fib may be formed on the initial thin film Fla at a high deposition rate by using the direct plasma P2.

Also, when the bulk thin film Fib is formed, the remote plasma P1 may be formed in addition to the direct plasma P2. Accordingly, the plasma efficiency can be further increased.

Accordingly, according to the substrate processing apparatuses 100 and 100a described above, the remote plasma P1 may be selectively formed in the reaction space A1, the direct plasma P2 may be selectively formed in the processing space A2, or the remote plasma P1 may be formed in the reaction space A1 and the direct plasma P2 may be formed in the processing space A2 simultaneously with the formation of the remote plasma P1 in the reaction space A1 as needed. For example, in a case in which plasma damage is a concern, the remote plasma P1 may be selectively formed in the reaction space A1 to supply radicals onto the substrate S, and in a case in which a high processing rate is required, the direct plasma P2 may be formed in the processing space A2 to supply ions and radicals onto the substrate S. Accordingly, when the substrate processing apparatuses 100 and 100a described above are used, processing efficiency for the substrate S can be increased by selectively using the remote plasma P1 and the direct plasma P2 as needed.

In addition, in the substrate processing apparatuses 100 and 100a described above, by applying a bias voltage to the susceptor 20 as needed, the adhesion efficiency of the precursor or the source gas can be increased to increase the deposition rate, thereby increasing productivity.

Further, according to the substrate processing apparatuses 100 and 100a described above, in the case of manufacturing a semiconductor device or a display device is manufactured by selectively using the remote plasma P1 and the direct plasma P2 as needed and/or selectively applying a bias voltage to the susceptor 20, when a thin film is deposited using atomic layer deposition (ALD) in patterns with a high aspect ratio, step coverage control, gap fill characteristic control, and thin film quality control in the patterns can be made possible.

It should be understood that the present disclosure has been described with reference to the embodiments illustrated in the drawings, but these are merely illustrative and various modifications and other equivalent embodiments can be made by those having ordinary knowledge in the art from the embodiments. Therefore, the true technical scope of the present disclosure should be determined by the technical idea of the appended claims.

What is claimed is:

1. An apparatus for processing a substrate comprising:
a chamber including a processing space in which the substrate is accommodatable and processible;
a susceptor coupled to the chamber to support the substrate in the processing space;
a gas supply device that is installed in a upper portion of the chamber and supplies a gas toward the susceptor; and
an RF power device configured to supply RF power to at least a portion of the gas supply device in order to form remote plasma in the gas supply device or to form direct plasma in the processing space.

2. The apparatus for processing a substrate according to claim 1,
wherein the gas supply device includes:
a shower head coupled to the chamber to inject a gas into the processing space;
a top plate that is disposed apart from the shower head and includes a gas inlet formed therein; and
an insulating side wall interposed between an end portion of the shower head and an end portion of the top plate to define a reaction space between the top plate and the shower head, and
the RF power device is selectively connected to the top plate or the shower head.

3. The apparatus for processing a substrate according to claim 2,
wherein in a case in which the RF power device is selectively connected to the shower head to supply the RF power to the shower head and the susceptor is connected to a ground portion, the direct plasma is formed in the processing space.

4. The apparatus for processing a substrate according to claim 2,
wherein in a case in which the RF power device is selectively connected to the shower head to supply the RF power to the shower head and the susceptor and the top plate are connected to a ground portion, the remote plasma is formed in the reaction space, and the direct plasma is formed in the processing space.

5. The apparatus for processing a substrate according to claim 2,
wherein in a case in which the RF power device is selectively connected to the top plate to supply the RF power to the top plate and the shower head is connected to a ground portion, the remote plasma is formed in the reaction space.

6. The apparatus for processing a substrate according to claim 5, further comprising a bias power supply unit selectively connected to the susceptor to apply a bias voltage to the susceptor.

7. The apparatus for processing a substrate according to claim 6,
wherein a precursor or a reaction gas is supplied to the substrate through the gas supply device to form a thin film on the substrate using an atomic layer deposition (ALD) method, the bias voltage is applied to the susceptor through the bias power supply unit in the case of supplying the precursor, and the bias voltage is not applied to the susceptor in the case of supplying the reaction gas.

8. The apparatus for processing a substrate according to claim 6,
wherein in a case in which the remote plasma is formed in the reaction space or the direct plasma is formed in the processing space, a bias voltage is applied to the susceptor through the bias power supply unit.

9. The apparatus for processing a substrate according to claim 2,
wherein the RF power device includes:
an RF power supply unit configured to generate the RF power; and
a splitter connected between the RF power supply unit and the gas supply unit to separate and selectively supply the RF power to the top plate and the shower head.

10. The apparatus for processing a substrate according to claim 2,
wherein the RF power device includes:
a first RF power supply unit selectively connected to the top plate via a first switch; and
a second RF power supply unit selectively connected to the shower head via a second switch, and
the RF power device controls the first switch and the second switch to form the remote plasma in the reaction space or to form the direct plasma in the processing space.

11. The apparatus for processing a substrate according to claim 10,
wherein in a case in which the top plate is electrically connected to the first RF power supply unit via the first switch to receive the RF power, and the shower head is connected to a ground portion, the remote plasma is formed in the reaction space.

12. The apparatus for processing a substrate according to claim 10,
wherein in a case in which the shower head is connected to the second RF power supply unit via the second switch to receive the RF power, and the susceptor is connected to a ground portion, the direct plasma is formed in the processing space.

13. The apparatus for processing a substrate according to claim 1,
wherein in an initial deposition stage in which a thin film is formed on the substrate, the remote plasma is formed in the gas supply device, and
in a bulk deposition stage in which the thin film is formed after the initial stage, the direct plasma is formed in the processing space.
